(19) United States
(12) Patent Application Publication
(10) Pub. No.: US 2024/0404932 A1
(43) Pub. Date: Dec. 5, 2024

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Kai-Fung Chang, Taipei City (TW); Ching-Hua Hsieh, Hsinchu (TW); Yi-Yang Lei, Taichung City (TW)

(73) Assignee: Taiwan Semiconductor Manufacturing Company, Ltd., Hsinchu (TW)

(21) Appl. No.: 18/325,006

(22) Filed: May 29, 2023

(51) Int. Cl. H01L 23/498; H01L 21/56; H01L 23/29; H01L 23/31; H01L 23/495

(52) U.S. Cl. CPC H01L 23/49827; H01L 21/565; H01L 23/295; H01L 23/3157; H01L 23/49568

(57) ABSTRACT

A semiconductor package and a manufacturing method for the semiconductor package are provided. The semiconductor package at least includes a redistribution layer, a semiconductor die, an interlink block, and a molding compound. The semiconductor die is disposed on the redistribution layer, and the interlink block is disposed on the redistribution layer and beside the semiconductor die. The interlink block includes an insulating encapsulant and through insulator vias penetrating through the insulating encapsulant. The molding compound disposed on the redistribution layer laterally wraps around the semiconductor die and the interlink block. The interlink block is spaced apart from the semiconductor die with the molding compound there-between. The through insulator vias are isolated from the molding compound by the insulating encapsulant.

### BACKGROUND

Following the developments of the three-dimensional integration technology for wafer level packaging, the demands of size reduction and high-performance interconnecting elements for high-density integration packages need to be satisfied.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 4 are schematic cross-sectional views of various stages in a manufacturing method of interlink blocks according to some exemplary embodiments of the present disclosure.

FIG. 5 is a schematic cross-sectional view of provided semiconductor dies according to some exemplary embodiments of the present disclosure.

FIG. 6 to FIG. 13 are schematic cross-sectional views of various stages in a manufacturing method of a semiconductor package according to some exemplary embodiments of the present disclosure.

FIG. 14A to FIG. 14F are schematic top views of interlink blocks for semiconductor packages according to some exemplary embodiments of the present disclosure.

FIG. 15 and FIG. 16 are schematic top views illustrating portions of semiconductor packages according to some exemplary embodiments of the present disclosure.

FIG. 17 is a schematic cross-sectional view illustrating a semiconductor package according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

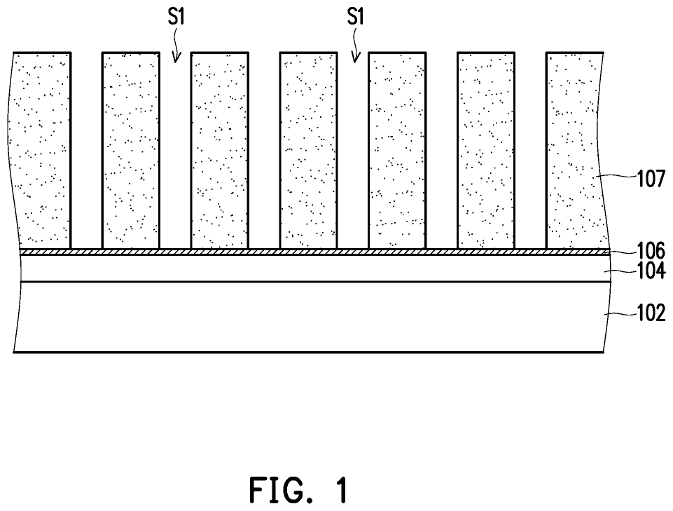

FIG. 1 to FIG. 4 are schematic cross-sectional views of various stages in a manufacturing method of interlink blocks according to some exemplary embodiments of the present disclosure.

Referring to FIG. 1, in some embodiments, a carrier 102 with a buffer layer 104 coated thereon is provided, the carrier 102 may be a glass carrier or any suitable carrier for carrying a semiconductor wafer or a reconstituted wafer for the manufacturing method of the semiconductor package. In some embodiments, the buffer layer 104 includes a debond layer and the material of the debond layer may be any material suitable for bonding and debonding the carrier 102 from the above layers or wafer disposed thereon. In some embodiments, the buffer layer 104 includes, for example, a light-to-heat conversion (“LTHC”) layer, and such layer enables room temperature debonding from the carrier by applying laser irradiation. Referring to FIG. 1, in some embodiments, the buffer layer 104 includes a dielectric material layer made of a dielectric material including benzocyclobutene (“BCB”), polybenzooxazole (“PBO”), or any other suitable polymer-based dielectric material. In certain embodiments, a seed layer 106 is formed on the buffer layer 104. In some embodiments, the seed layer 106 includes at least one metallic layer formed by sputtering or deposition. In one embodiment, the seed layer 106 includes a copper layer. Later, a mask pattern 107 is formed directly on the seed layer 106, and the mask pattern 107 is formed with openings S1 exposing portions of the seed layer 106 at the locations corresponding to the locations of the to-be-formed TIVs. In some embodiments, the mask pattern 107 is formed by forming a photoresist layer (not shown) by spin coating and then patterning the photoresist layer to form the openings S1 through photolithographic and etching processes. In some embodiments, the openings S1 are of substantially the same sizes and have substantially the same top-view shapes. In some embodiments, the openings S1 may be categorized into different types with different cross-section area sizes and/or various top-view shapes. It is understood that the number of the openings and relative dimensions/shapes of the openings shown in the figures or described in the embodiments are merely exemplary and illustrative, but are not intended to further limit the scope of the disclosure.

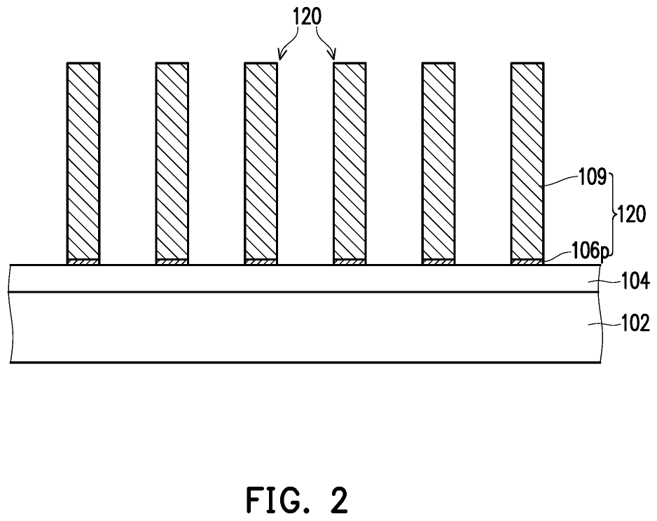

Referring to FIG. 2, in some embodiments, through insulation (or insulator) vias (“TIVs”) 120 are formed on the buffer layer 104 over the carrier 102 after removing the mask pattern 107. In some embodiments, along with the subsequently formed fan-out redistribution layer(s), the TIVs 120 may function as through integrated fan-out (“InFO”) vias. In some embodiments, as seen in FIG. 1 and FIG. 2, the formation of the TIVs 120 includes forming the mask pattern 107 with openings S1 on the seed layer 106, and the openings S1 exposing portions of the seed layer 106 at predetermined locations. Afterwards, using the seed layer 106 as the seed, a metallic material 109 is formed inside the openings S1 and on the seed layer 106 to fill up the openings S1 by electroplating. Alternatively, the metallic material 109 is formed inside the openings S1 and fills up the openings S1 by deposition. Later, the mask pattern 107 is removed by performing an etching process or a stripping process, and the seed layer 106 is partially removed using the TIVs 120 as the mask by performing an etching process. That is, the seed layer 106 that is not covered by the metallic material 109 is removed, and the seed pattern 106P (the remained seed layer 106 located below the metallic material 109. In some embodiments, the seed layer 106 is partially removed to form the seed pattern 106P along with the removal of the mask pattern 107. Referring to FIG. 1 and FIG. 2, the TIVs 120 are formed inside the openings S1 (FIG. 1). In some embodiments, each of the TIVs 120 includes the seed pattern 106P and the metallic material 109 located directly on the seed pattern 106P. Even though the seed layer 106 is partially removed or patterned, the buffer layer 104 is remained.

In some embodiments, the material of the seed layer 106 varies depending on the later-formed metallic material of TIVs. In one embodiment, the seed layer 106 includes a copper layer. In certain embodiments, the seed layer 106 (in FIG. 1) is formed by firstly sputtering a composite layer of a titanium layer and a copper layer over the buffer layer 104 on the carrier 102, while the metallic material 109 is subsequently formed by electroplating copper or a copper alloy to fill the openings S1 of the mask pattern 107. However, it is appreciated that the scope of this disclosure is not limited to the materials and descriptions disclosed above. In some embodiments, the TIVs 120 are metallic pillars or columns with round, oval or elliptical top-view shapes or even polygonal shapes from the top-views. In some embodiments, the TIVs 120 are plated copper pillars having a dimension (or diameter) ranging from about 10 microns to about 200 microns.

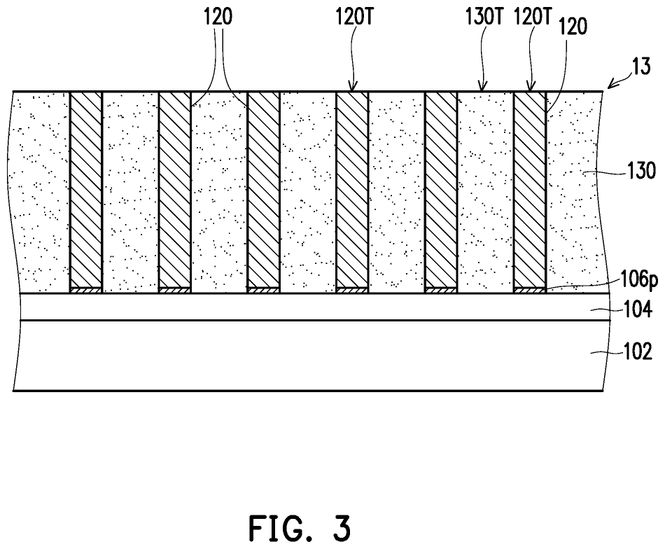

Referring to FIG. 3, in some embodiments, an encapsulant 130 is formed over the carrier 102 to cover the TIVs 120 on the buffer layer 104 to form a molded structure 13, and the TIVs 120 located over the carrier 102 are fully wrapped by and molded in the encapsulant 130. In some embodiments, the encapsulant 130 covers the buffer layer 104 and fills between the TIVs 120, and the molded structure 13 is in a wafer form or in a panel form. In certain embodiments, the encapsulant 130 fully covers all of the TIVs 120 and at least laterally wrapping entire sidewalls of the TIVs 120, while surfaces 120T (top surfaces in FIG. 3) of the TIVs 120 are exposed. In some embodiments, the formed encapsulant 130 encapsulates the TIVs 120 and fully covers the top surfaces 120T of the TIVs 120, and a trimming process including a planarization process is performed to remove the extra encapsulant material above the top surfaces 120T of the TIVs 120.

In some embodiments, the encapsulant 130 is formed by the molding technology such as injection molding, transfer molding, compression molding or over-molding. In exemplary embodiments, the molding technology utilizes a mold chase with a release film coated on its inner surface to control the cured molded material covers the TIVs 120. In exemplary embodiments, the material of the encapsulant 130 includes a polymeric material free of filler particles, and the polymeric material is selected from low-temperature curable polyimide materials, epoxy resins, BCB, PBO, or any other suitable polymeric dielectric material. Since the polymeric material free of filler particles has better flowability, the encapsulant formed of such polymeric material offers better coverage and filling capability over the TIVs 120. In some embodiments, the material of the encapsulant 130 is an insulating material and includes at least one type of filler-containing resins. In exemplary embodiment, the resins include epoxy resins, phenolic resins or silicon-containing resins, and the fillers are particles made of non-melting inorganic materials. For example, the fillers include metal oxide particles, silica particles or silicate particles with average particle sizes ranging from about 3 microns to about 20 microns. Better surface smoothness and flatness of the encapsulant is achievable if zero or fine filler particles are used.

In some embodiments, the trimming process includes performing a planarization process, such as chemical-mechanical polish (CMP) process, mechanical grinding process, laser ablation process and/or the combination thereof, to remove the extra material of the encapsulant 130 above the top surfaces 120T of the TIVs 120 until the top surfaces 120T of the TIVs 120 are exposed. That is, the top surfaces 120T of the TIVs 120 are levelled with and flush with the polished surface 130T of the encapsulant 130. In some embodiments, the trimming process or the planarization may be omitted, if the top surfaces 120T of the TIVs 120 are already exposed from the encapsulant 130. Later, by examining the exposed surfaces 120T, an inspection process is performed to check whether the TIVs 120 are undamaged (without voids or defective spots) and have substantially the same height and the top surfaces 120T of the TIVs 120 are well exposed from the encapsulant 130. If any TIV is found defective or inoperative, it is marked and will be excluded later.

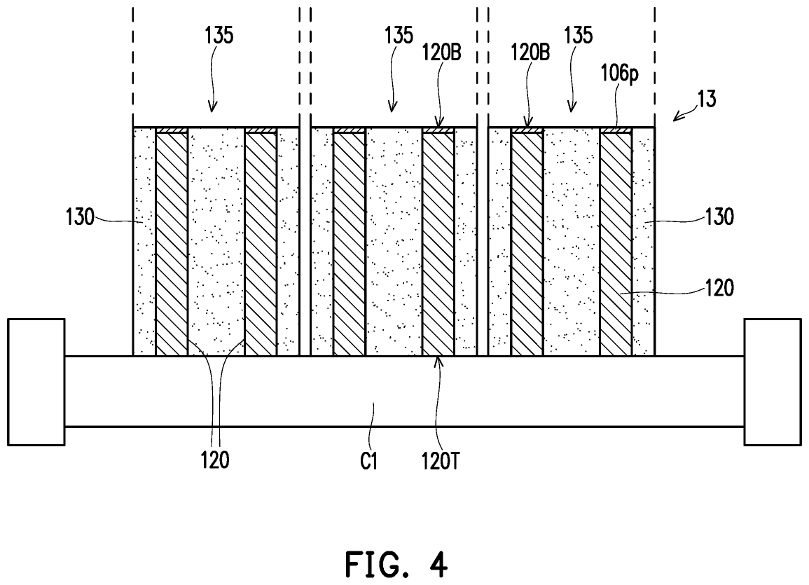

Referring to FIG. 3 and FIG. 4, the molded structure 13 is transferred to another carrier C1. In some embodiments, the carrier C1 is a film-type carrier. In certain embodiments, the carrier C1 is attached to the surface of the molded structure 13, and the carrier C1 contacts the exposed surfaces 120T of the TIVs 120 and the surface 130T of the encapsulant 130. Later, the whole structure including the carriers 102, C1 and the molded structure 13 is flipped (turned upside down), the molded structure 13 is separated from the carrier 102, and later the carrier 102 along with the buffer layer 104 are removed. As the molded structure 13 is flipped and detached from the carrier 102, the surfaces 120B (opposite to the surfaces 120T) of the TIVs 120 are exposed, while the surfaces 120T are covered by the carrier C1. As seen in FIG. 4, the seed pattern 106P of the TIVs 120 are exposed from the encapsulant 130. In some embodiments, a dicing process is performed to cut the molded structure 13 along the cut lanes (represented in dotted lines) into a plurality of interlink blocks 135. In some embodiments, the dicing process includes performing mechanical sawing or laser cutting. In FIG. 4, the dotted line represents the cutting lanes of the whole structure used in the subsequent dicing process, and some of the TIVs 120 are arranged close to but not on the cutting lanes, so that sidewalls of the TIVs 120 are exposed after the dicing process.

Later, by examining the exposed surfaces 120B, another inspection process is performed to check whether any of the TIVs 120 is incomplete or has voids or damages and whether the surfaces 120B of the TIVs 120 are well exposed from the encapsulant 130. If any TIV is found defective or inoperative during either inspection process, the block containing such defective TIV will be rejected and excluded. That is, through the inspection process(es), the remained interlink blocks 135 contain only known good through vias.

In some embodiments, each of the interlink blocks 135 includes multiple TIVs 120 laterally wrapped by the encapsulant 130. In some embodiments, the opposite surfaces 120B/120T of the pillar shaped TIVs 120 are exposed from the encapsulant 130, while the sidewalls of the TIVs 120 are fully wrapped by the encapsulant 130.

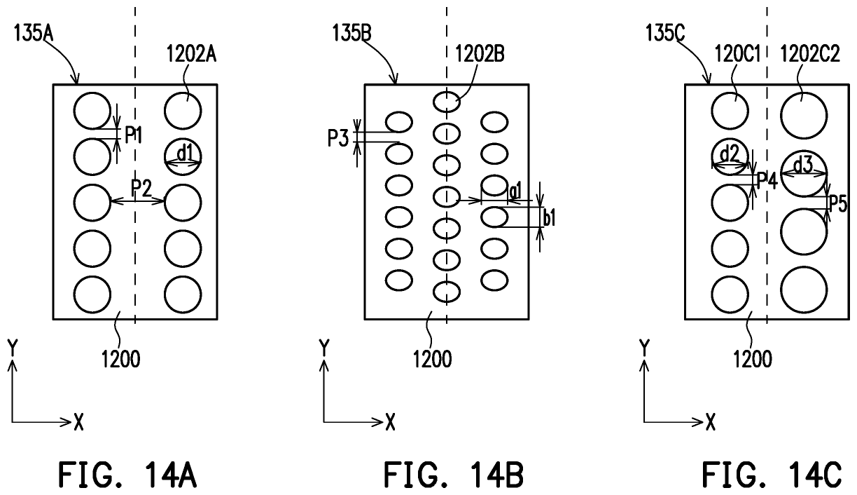

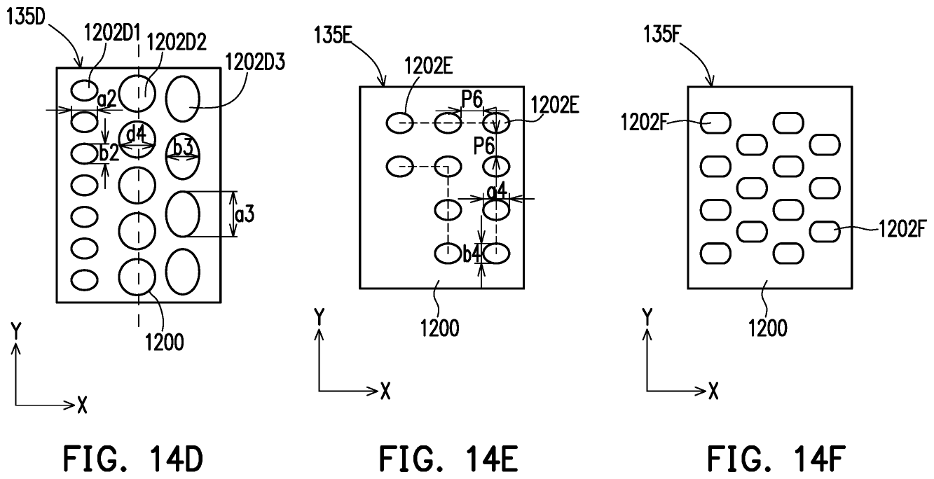

FIG. 14A to FIG. 14F are schematic top views of interlink blocks applicable for semiconductor packages according to some exemplary embodiments of the present disclosure. Referring to FIG. 14A, the interlink block 135A includes a plurality of TIVs 1202A inlaid in the encapsulant 1200 and the TIVs 1202A are arranged in an array. In FIG. 14A, for the interlink block 135A, each TIV 1202A has a circular top view and a diameter d1, and the TIVs 1202A are aligned and arranged in two columns along the Y-direction and in five rows along the X-direction perpendicular to the Y-direction. In some embodiments, the TIVs 1202A in the same column are spaced apart from each other with the same pitch P1, while the TIVs 1202A in the same row are also spaced apart from each other with the same pitch P2.

In FIG. 14B, for the interlink block 135B, the TIVs 1202B are arranged in an array and are aligned and arranged in three columns along the Y-direction. As seen in FIG. 14B, the TIVs 1202B in one column are arranged offset from the TIVs 1202B in the next column, so that TIVs 1202B of the left and right columns are arranged in six rows along the X-direction and there are seven TIVs 1202B in the middle column. In some embodiments, the TIVs 1202B in the same column are spaced apart from each other with the same pitch P3. For example, each TIV 1202B has an elliptical top-view shape and has substantially the same size (e.g. the same length a1 in the major axis and the same width b1 in the minor axis of the ellipse). From the top views of FIG. 14A and FIG. 14B, the blocks 135A and 135B are symmetrical blocks as the arrangement of the TIVs are symmetrical to the middle line (in dotted lines) of the block.

Referring to FIG. 14C, the interlink block 135C includes TIVs 1202C1 (circular top views) and larger TIVs 1202C2 (circular top views) inlaid in the encapsulant 1200. In FIG. 14C, five TIVs 1202C1 (each circular TIV 1202C1 has the same diameter d2) are aligned and arranged as one column (left column) along the Y-direction, while four TIVs 1202C2 (each circular TIV 1202C2 has the same diameter d3, d3>d2) are aligned and arranged as one column (right column) along the Y-direction. As seen in FIG. 14C, the TIVs 1202C1 in one column are spaced apart from each other with the same pitch P4, while the TIVs 1202C2 in the next column are spaced apart from each other with the same pitch P5.

Referring to FIG. 14D, the interlink block 135D includes TIVs 1202D1 (elliptical top views), larger TIVs 1202D2 (circular top views) and largest TIVs 1202D3 (elliptical top views) inlaid in the encapsulant 1200. In FIG. 14D, seven TIVs 1202D1 are aligned and arranged as one column (left column) along the Y-direction, five TIVs 1202D2 (each circular TIV 1202D2 has the same diameter d4) are aligned and arranged as one column (middle column) along the Y-direction, and four TIVs 1202D3 are aligned and arranged as one column (right column) along the Y-direction. As seen in FIG. 14D, each TIVs 1202D1 has an elliptical top-view shape and has substantially the same size (e.g. the same length a2 in the major axis (X-direction) and the same width b2 in the minor axis (Y-direction) of the ellipse), and each TIVs 1202D3 has an elliptical top-view shape and has substantially the same size (e.g. the same length a3 in the major axis (Y-direction) and the same width b2 in the minor axis (X-direction) of the ellipse). That is, the elliptical column TIVs 1202D1 are arranged with the major axis parallel to the X-direction, while the TIVs 1202D3 are arranged with the major axis parallel to the Y-direction. In some embodiments, as a3>b3≥d4, each TIV 1202D3 is larger than the TIV 1202D2. In some embodiments, as a3 is larger than a2 (a3>a2) and b3 is larger than b2 (b3>b2), each TIV 1202D3 is larger than the TIV 1202D1. From the top views of FIG. 14C and FIG. 14D, the blocks 135C and 135D are asymmetrical blocks as the arrangement of the TIVs are asymmetrical to the middle line of the block.

Referring to the top view of FIG. 14E, the interlink block 135E includes a plurality of TIVs 1202E (elliptical top views) inlaid in the encapsulant 1200 and the spaced apart TIVs 1202E are arranged as two inverse L in parallel. In FIG. 14E, for the interlink block 135E, the TIVs 1202E are spaced apart from each other in either the same column or the same row with the same pitch P6, and each TIV 1202E has the same top-view shapes and sizes (e.g. the same length a4 in the major axis and the same width b4 in the minor axis of the ellipse).

In FIG. 14F, in some embodiments, the interlink block 135F includes TIVs 1202F aligned and arranged in four columns along the Y-direction, the TIVs 1202F in one column are arranged offset from the TIVs 1202F in the next column, so that the TIVs of the left column and of the column next to its next column are aligned as four rows along the X-direction, and the TIVs of the right column and of the column next to its next column are aligned as three rows along the X-direction. In some embodiments, each TIVs 1202F has an oval or stadium shape from the top view and has substantially the same top-view area (i.e. the same cross-section area size). In some embodiments, the interlink blocks 135E and 135F may function as corner blocks and may be disposed at or near the corners of the package.

Through the formation of the interlink blocks 135 and 135A-135F, the through vias penetrating through the insulating material are preformed and pre-packed as groups in block forms. Further, depending on the design of the integrated devices or components, various types of TIVs in different sizes (cross-section area sizes or diameters), shapes, or pitches may be incorporated for better interconnection.

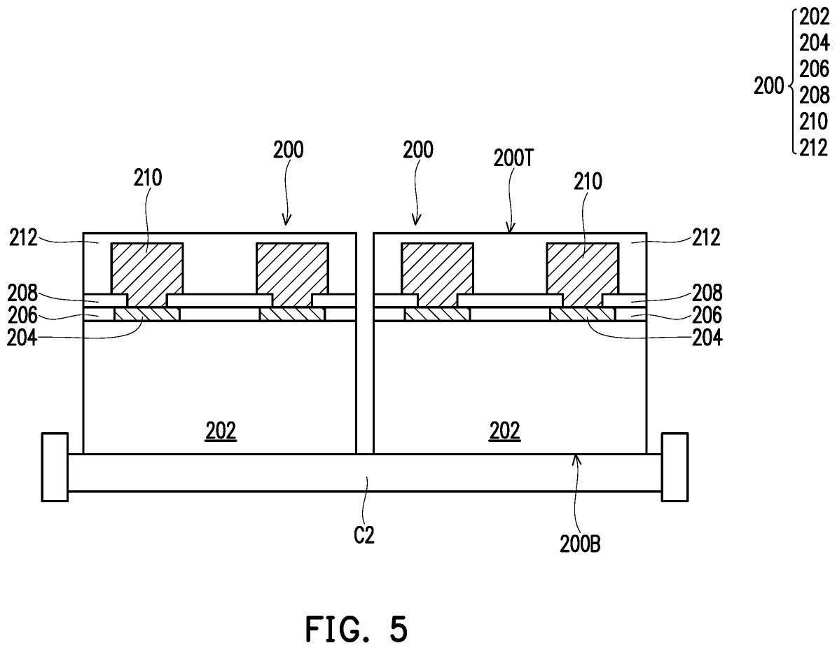

FIG. 5 is a schematic cross-sectional view of provided semiconductor dies according to some exemplary embodiments of the present disclosure. Herein, chips and dies may be used interchangeably throughout the whole contexts of the disclosure.

Referring to FIG. 5, in some embodiments, semiconductor dies 200 including semiconductor devices or integrated circuit components are formed on a temporary carrier C2. In some embodiments, the semiconductor dies 200 may be formed from a wafer or a reconstructed wafer (not shown) that includes a plurality of semiconductor dies 200 arranged in an array, and a singulation process is performed to the wafer, so that individual semiconductor dies 200 are formed.

In some embodiments, referring to FIG. 5, each die 200 includes a semiconductor substrate 202, a plurality of conductive pads 204, a passivation layer 206, a post passivation layer 208, a plurality of conductive posts 210, and a protection layer 212. In some embodiments, the conductive pads 204 are disposed over the semiconductor substrate 202, and the passivation layer 206 is formed over the semiconductor substrate 202 with contact openings that expose the conductive pads 204. For example, the semiconductor substrate 202 may be a silicon substrate or a silicon-on-insulator substrate, and the semiconductor substrate 202 includes active components (e.g., transistors, diodes or the like) and/or passive components (e.g., resistors, capacitors, inductors or the like) formed therein. The conductive pads 204 may be aluminum pads, copper pads, or other suitable metal pads. The passivation layer 206 may be or include a silicon oxide layer, a silicon nitride layer, a silicon oxy-nitride layer, or a dielectric layer formed by other suitable dielectric materials. The post-passivation layer 208 formed over the passivation layer 208 may be or include a polyimide (PI) layer, a polybenzoxazole (PBO) layer, or a dielectric layer formed by other suitable polymers. In addition, the conductive posts 210 are formed on the conductive pads 204 by plating. In some embodiments, the conductive posts 210, functioning as contact terminals, are electrically connected with the conductive pads 204. The protection layer 212 is formed on the post-passivation layer 208 and fully covers the conductive posts 210. That is, the conductive posts 210 are not exposed and protected by the protection layer 212. The protection layer 212 may be or include a polymeric material such as PI, PBO or other inorganic dielectric material. The conductive posts 210 may be or include copper posts, copper alloy posts or other suitable metal posts. In some embodiments, the top surface 200T of the semiconductor die 200 that faces away from the carrier C2 may be considered as the active surface of the die 200, while the back surface 200B of the semiconductor die 200 is covered by the carrier C2.

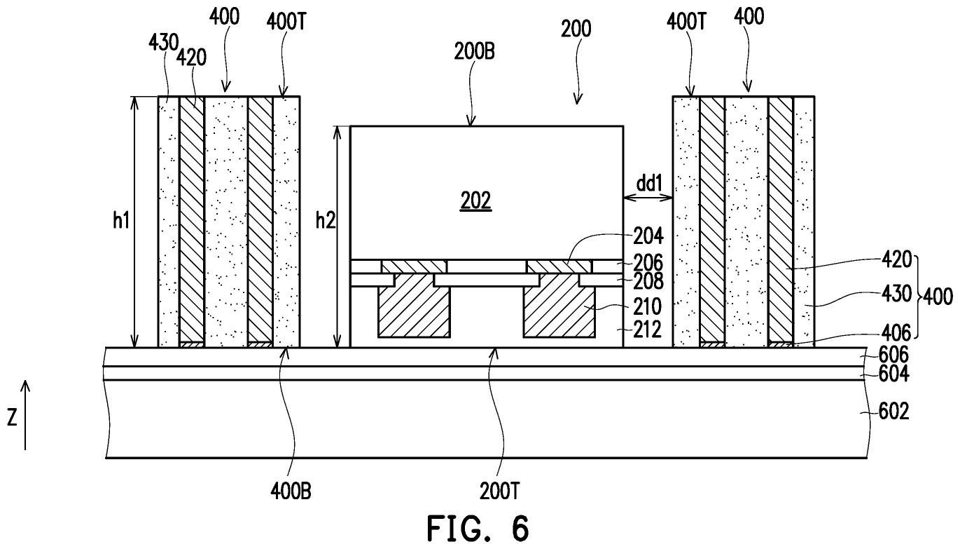

FIG. 6 to FIG. 13 are schematic cross-sectional views of various stages in a manufacturing method of a semiconductor package according to some exemplary embodiments of the present disclosure. In exemplary embodiments, the manufacturing method of the semiconductor package may be part of a wafer-level packaging process. In some embodiments, one chip (or die) is shown to represent one or plural chips (or dies) of the wafer, and one or more packages 10 are shown to represent plural semiconductor packages obtained following the semiconductor manufacturing method.

Referring to FIG. 6, a carrier 602 with a buffer layer 604 coated thereon is provided, and the carrier 602 and the buffer layer 604 are similar to the carrier 102 and the buffer layer 104 described in the previous paragraphs. In some embodiments, the buffer layer 604 includes a debond layer, such as a LTHC layer. Referring to FIG. 6, in some embodiments, a die attach film 606 is formed on the buffer layer 604 to provide better attachment for subsequently placed or mounted components.

Referring to FIG. 6, one or more semiconductor dies 200 are provided (one die is shown as an example) and disposed on the die attach film 606 over the buffer layer 604 on the carrier 602. Also, interlink blocks 400 are provided and disposed on the die attach film around the semiconductor die 200. In some embodiments, the semiconductor chip(s) 200 and the interlink blocks 400 are picked and placed on the die attach film 606. In exemplary embodiments, at least one semiconductor die 200 is similar to or substantially the same as the semiconductor die 200 illustrated in FIG. 5, and may include the semiconductor substrate 202, the conductive pads 204, the passivation layer 206, the post passivation layer 208, the conductive posts 210, and the protection layer 212 as illustrated in FIG. 5. However, it is understood that the same type of chips or different types of chips may be provided among the provided plural semiconductor chips, and more than one types of semiconductor chips may be provided. In some embodiments, the semiconductor die 200 includes one or more selected from logic chips, memory chips, voltage regulator chips, digital chips, analog chips or mixed signal chips, such as application-specific integrated circuit (“ASIC”) chips, sensor chips, and wireless and radio frequency chips. In some embodiments, the semiconductor die 200 includes integrated circuits (ICs) integrating central processing unit (CPU), graphics processing unit (GPU), system-on-a-chip (SoC), application processors (AP), microcontrollers, and the like. In exemplary embodiments, the interlink blocks 400 may be similar to the interlink blocks 135 and 135A-135F as described in previous paragraphs. For example, the interlink block 400 includes TIVs 420 embedded in the encapsulant 430, and the TIVs 420 includes seed pattern 406. As described previously, the encapsulant 430 includes an insulating polymeric material having a dielectric constant different from silicon.

In some embodiments, in FIG. 6, the semiconductor die(s) 200 is disposed on the die attach film 606 with its frontside or active surface 200T in contact with the die attach film 606, while the surface 200B (the semiconductor substrate 202) of the semiconductor die(s) 200 faces up and is exposed. Hence, the frontside surface 200T of the semiconductor die(s) 200 is attached to the die attach film 606. In some embodiments, the interlink blocks 400 are placed directly on the die attach film 606 with their backside surfaces 400B in contact with the die attach film 606, and the frontside surfaces 400T of the interlink blocks 400 faces up and are exposed. In some embodiments, the interlink blocks 400 are attached to the die attach film 606, and the seed patterns 406 of the TIVs 420 are attached to the die attach film 606. As seen in FIG. 6, the conductive posts 210 of the die 200 are separate from the die attach film 606 by the protection layer 212.

In some embodiments, the interlink blocks 400 are disposed beside and around the semiconductor die(s) 200 over the carrier 602. In some embodiments, the interlink blocks 400 are arranged in a way that the TIVs 420 inside the interlink blocks 400 surround the semiconductor die(s) 200. In some embodiments, as shown in FIG. 6, the interlink blocks 400 are located beside and spaced apart from the semiconductor die(s) 200. In some embodiments, the interlink block 400 is spaced apart from the semiconductor die(s) 200 with a distance dd1. In some embodiments, the interlink blocks 400 are disposed beside and next to the semiconductor die 200.

Referring to FIG. 6, in some embodiments, the semiconductor die(s) 200 and the interlink blocks 400 have different heights (thicknesses in the Z-direction). In exemplary embodiments, the semiconductor die(s) 200 has a height h2 smaller than the height h1 of the interlink blocks 400. That is, the surface 200B of the semiconductor die(s) 200 is lower than the surfaces 400T of the interlink blocks 400.

In alternative embodiments, the semiconductor die(s) 200 and the interlink blocks 400 may have substantially the same height. In other embodiments, the semiconductor die(s) 200 is thicker than the interlink blocks 400.

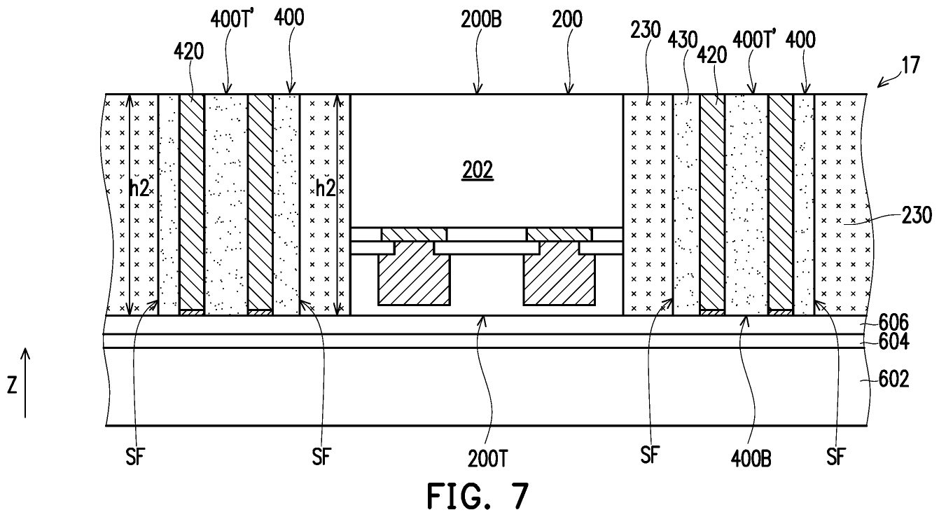

Referring to FIG. 7, in some embodiments, a molding compound 230 is formed over the carrier 602 covering the semiconductor die(s) 200 and the interlink blocks 400 (including TIVs 420) located over the carrier 602, so that the interlink blocks 400 and the semiconductor die(s) 200 are molded in the molding compound 230 to form a molded structure 17. In some embodiments, the molding compound 230 covers the die attach film 606, fills between the semiconductor die(s) 200 and the interlink blocks 400, and fills up spaces between the semiconductor die(s) 200 and the interlink blocks 400. In certain embodiments, the molded structure 17 is in a wafer form or in a panel form. As there may be height differences between the semiconductor die(s) 200 and the interlink blocks 400, the molding compound 230 at least fully covers the lowest one among the molded components. As seen in FIG. 7, the molding compound 230 wraps around and covers entire sidewalls of the semiconductor die(s) 200 and the interlink blocks 400.

In some embodiments, the molding compound 230 is formed by the molding technology such as injection molding, transfer molding, compression molding or over-molding. In exemplary embodiments, the molding technology ensures the cured molded material covering the interlink blocks 400 and the semiconductor die(s) 200. In some embodiments, the material of the molding compound 230 is an insulating material and includes at least one type of filler-containing resins. In exemplary embodiment, the resins include epoxy resins, phenolic resins or silicon-containing resins, the fillers are particles made of non-melting inorganic materials, and the fillers include metal oxide particles, silica particles or silicate particles with average particle sizes ranging from about 3 microns to about 20 microns.

In some embodiments, the material of the molding compound 230 is substantially the same as the material of the encapsulant 430 of the interlink blocks 400. In some embodiments, the material of the molding compound 230 is different from the material of the encapsulant 430 of the interlink blocks 400. In some embodiments, the material of the encapsulant 430 includes epoxy resins free of filler particles, and the material of the molding compound 230 includes epoxy resins with filler particles (such as metal oxide particles or silica particle). In some embodiments, the material of the encapsulant 430 includes epoxy resins and first fillers, and the material of the molding compound 230 includes epoxy resins and second fillers that have larger particle sizes than the first fillers.

In some embodiments, for the molded structure 17 as shown in FIG. 7, there are interfaces SF existing between the sidewalls of the interlink blocks 400 and the molding compound 230. Disregarding the material choices, the interfaces SF exist between the encapsulant 430 and the molding compound 230 because the interlink blocks 400 are formed and provided before the formation of the molding compound 230.

In exemplary embodiments, the molding compound 230 is formed to fully cover the surfaces 400T of the interlink blocks 400 and the surface 200B of the semiconductor die(s) 200 (i.e. over-molding) and then a trimming process including a planarization process is performed to remove the extra molding compound. In some embodiments, since the semiconductor die(s) 200 is lower (due to the smaller height/thickness of the semiconductor die(s) 200), the planarization process is performed to remove portions of the interlink blocks 400 that are located above the surface 200B and remove extra molding compound material above the surface 200B of the semiconductor die(s) 200, in order to achieve the same thickness (the same horizontal level). In some embodiments, the planarization process includes a chemical-mechanical polish (CMP) process, a mechanical grinding process, a laser ablation process and/or the combination thereof. After the polishing or grinding process, a cleaning step may be optionally performed to clean and remove the residues generated from the grinding or polishing process. However, the disclosure is not limited thereto, and the planarization process may be performed through any other suitable method.

In some embodiments, during the trimming process, the interlink blocks 400 are trimmed to the same level (e.g. having the same height h2) as the semiconductor die(s) 200, and the extra material of the molding compound 230 above the surface 200B of the semiconductor die(s) 200 is removed until the surface 200B is exposed. That is, the polished surfaces 400T′ of the interlink blocks 400 are levelled with and flush with the surface 200B of the semiconductor die(s) 200. In some embodiments, as the interlink blocks 400 are trimmed to become thinner, portions of the encapsulant 430 and portions of the TIVs 420 are removed (polished or grinded) but the ends of the TIVs 420 are still exposed from the encapsulant 430 for further electrical connection.

In some embodiments, when the interlink blocks 400 and the semiconductor die(s) 200 have substantially the same height/thickness, a trimming process may still be performed to remove the extra material of the molding compound 230 above the surfaces of the semiconductor die(s) 200 and the interlink blocks 400, so that the TIVs 420 are exposed for further electrical connection.

In some embodiments, as the active surface 200T of the semiconductor die(s) 200 faces down and covered by the die attach film 606, the trimming process is performed to the backside of the semiconductor die(s) 200. Since the trimming process is performed toward the semiconductor substrate 202 (i.e. performed to the backside surface 200B), the process window of the trimming process becomes larger as slight over-polishing occurred at the backside of the semiconductor substrate may be acceptable. Moreover, by forming and providing the interlink blocks 400, the TIVs 420 are fixed within the encapsulant 430 before forming the molding compound 230, and the TIVs 420 are not tilted or collapsed during the molding process. Hence, the reliability of the TIVs 420 is further improved.

As seen in FIG. 7, the surface 200B of the semiconductor die(s) 200 and the surfaces 400T′ of the interlink blocks are exposed from the molding compound 230. In some embodiments, for the molded structure 17 as shown in FIG. 7, there are interfaces SF existing between the sidewalls of the interlink blocks 400 and the molding compound 230. Here, the interfaces SF exist between the encapsulant 430 and the molding compound 230 because the interlink blocks 400 that include TIVs 420 wrapped by the encapsulant 430 are formed and provided before the molding process of the molding compound 230. Since the interlink blocks 400 with known good TIVs 420 are formed and provided before the formation of the molding compound 230, the possibility of rework due to the failure of the TIVs is greatly reduced, the product yield is increased and the production cost is decreased accordingly.

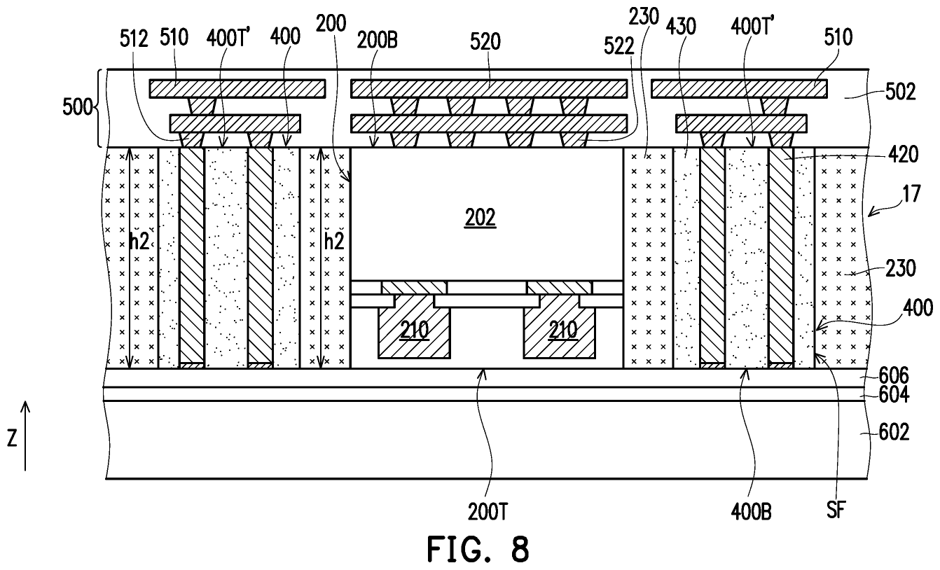

Referring to FIG. 8, in some embodiments, a redistribution layer 500 is formed on the molding compound 230, on the semiconductor die(s) 200 and on the interlink blocks 400. In some embodiment, the redistribution layer 500 is formed on the surfaces 400T′ of the interlink blocks 400 and on the surface 200B of the semiconductor die(s) 200. The formation of the redistribution layer 500 includes sequentially forming one or more layers of dielectric materials and one or more metallization (wiring) layers in alternation. In certain embodiments, the redistribution layer 500 includes at least wiring patterns 510 and metallization patterns 520 sandwiched between the dielectric material 502. In FIG. 8, at least the bottom wiring patterns 512 of the wiring patterns 510 are physically and electrically connected to the TIVs 420 of the interlink blocks 400. In some embodiments, the metallization patterns 520 including bottom thermal vias 522 are in physically contact with the substrate 202 of the semiconductor die(s) 200, and the metallization patterns 520 are electrically floating and may function as thermal dissipating elements. It is understood that the bottom thermal vias 522 and the bottom wiring patterns 512 may be formed at the same time during the formation of the bottom metallization layer (or wiring layer) of the redistribution layer 500 and both the bottom thermal vias 522 and the bottom wiring patterns 512 may be part of the bottom wiring layer.

In some embodiments, the wiring patterns 510 and metallization patterns 520 are part of the metallization layers, and the material of the metallization layer(s) includes copper, titanium, nickel, aluminum, tungsten, silver and/or alloys thereof. In some embodiments, the material of the dielectric material 502 includes polyimide, BCB, or PBO. In some embodiments, as the redistribution layer 500 is formed on the backside of the semiconductor die(s) 200, the redistribution layer 500 may be considered as a backside redistribution layer electrically connected with the TIVs 420 of the interlink blocks 400. In certain embodiments, as the underlying molded structure 17 (including the molding compound 230, the semiconductor die 200 and the interlink blocks 400) provides better planarization and evenness, the later-formed redistribution layer 500, especially the metallization patterns with thin line width or tight spacing, can be formed with uniform line-widths or even profiles over the flat and levelled molded structure 17, resulting in improved line/wiring reliability.

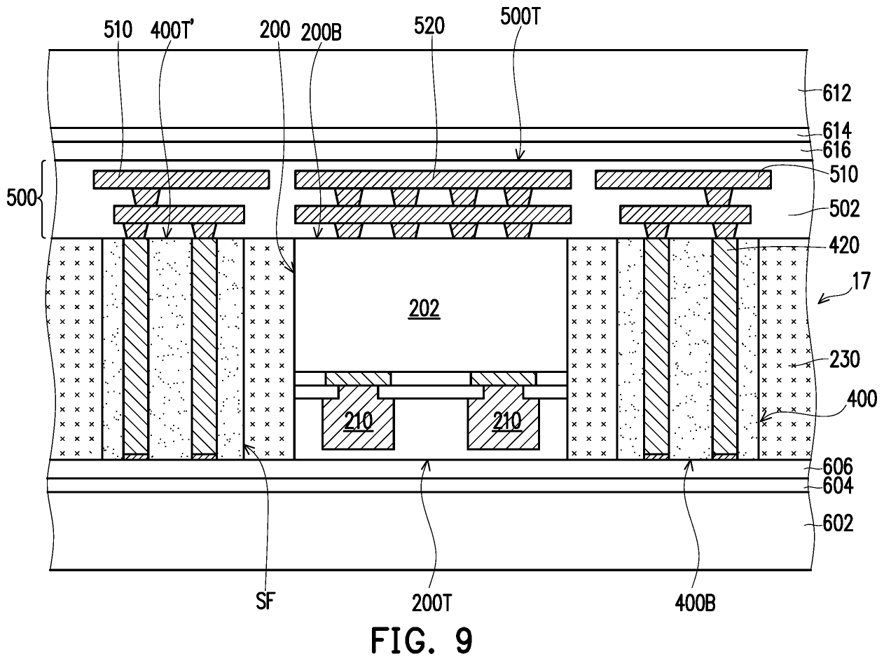

Referring to FIG. 9, following the formation of the redistribution layer 500, a carrier 612 with a buffer layer 614 and a die attach film 616 thereon is provided and attached to the redistribution layer 500. For example, the carrier 612, the buffer layer 614 and the die attach film 616 are similar or substantially the same as the carrier 602, the buffer layer 604 and the die attach film 606 as described in the previous paragraph(s). In some embodiments, the die attach film 616 is attached to the top surface 500T of the redistribution layer 500.

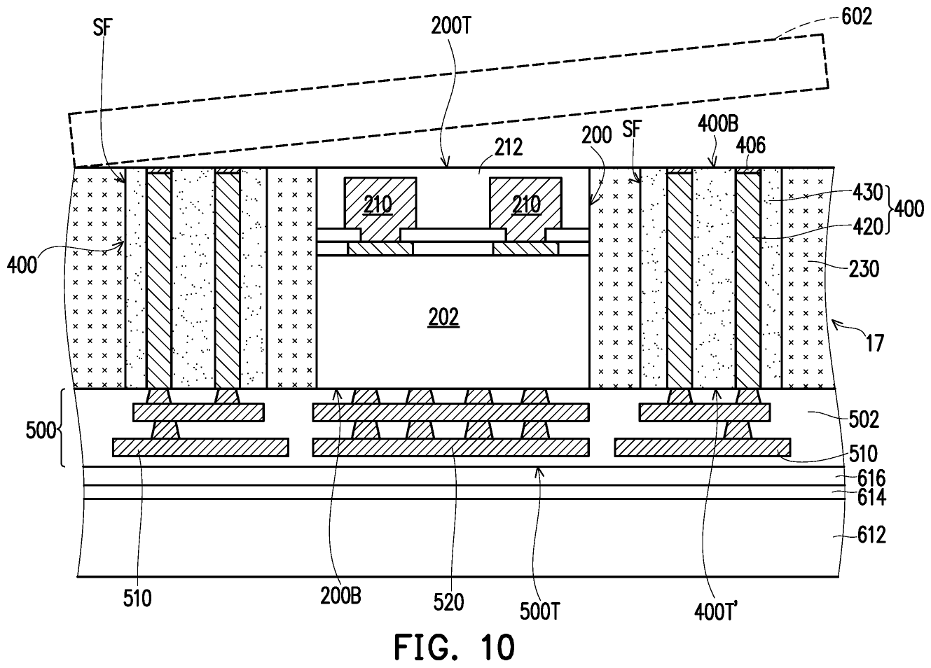

Referring to FIG. 10, the whole structure including the carriers 602, 612 and the molded structure 17 is flipped (turned upside down), the molded structure 17 is separated from the carrier 602, and later the carrier 602 is removed. As the molded structure 17 is flipped and detached from the carrier 602, the surfaces 400B (opposite to the surfaces 400T′) of the interlink blocks 400 are exposed, and the surface 200T of the semiconductor die(s) 200 is exposed. As seen in FIG. 10, in some embodiments, the seed patterns 406 of the TIVs 420 of the interlink blocks 400 are exposed from the encapsulant 430, and the protection layer 212 of the semiconductor die(s) 200 is exposed.

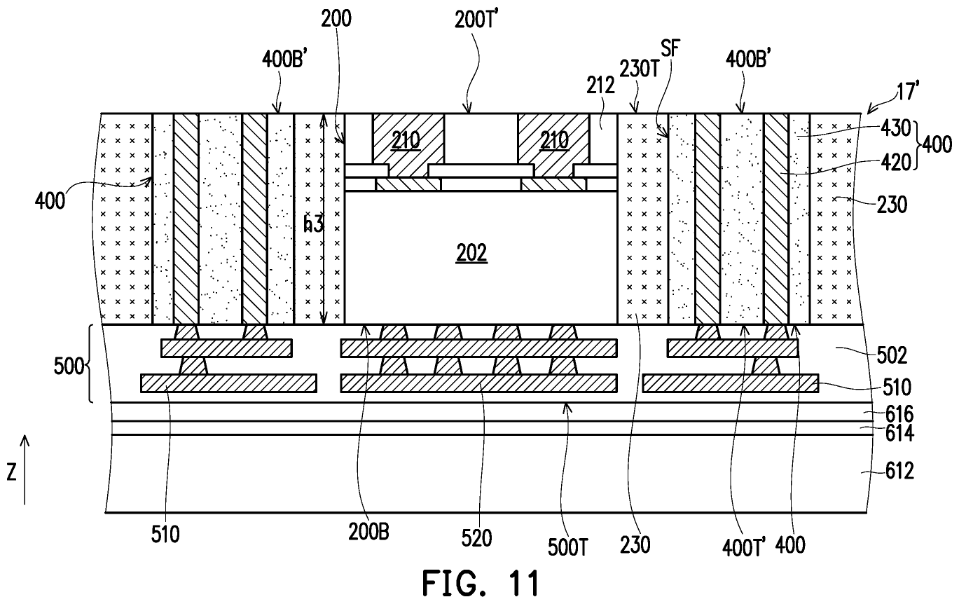

Referring to FIG. 10 and FIG. 11, a planarization process is performed to remove a portion of the molded structure 17 to become the molded structure 17′ with a uniform height h3 (thickness in Z-direction). In some embodiments, the planarization process includes a chemical-mechanical polish (CMP) process, a mechanical grinding process, or the combination thereof. After the polishing or grinding process, a cleaning step may be optionally performed. In some embodiments, the planarization process is performed to the semiconductor die(s) 200 to remove the protection layer 212 and expose the conductive posts 210, at the same time, during the planarization process, portions of the interlink blocks 400 are also removed. As seen in FIG. 11, after the planarization process, the conductive posts 210 are exposed from the polished surface 200T′ with the remained protection layer surrounding the conductive posts 210. In some embodiments, the ends of the TIVs 420 are exposed from the polished surface 400B′ of the interlink blocks 400 but the seed patterns 406 (see FIG. 10) are removed after the planarization process. During the planarization process, extra molding compound material above the surface 200T′ of the semiconductor die(s) 200 and the surfaces 400B′ of the interlink blocks 400 is removed, in order to achieve the same horizontal level. After the planarization process, the polished surfaces 400B′ of the interlink blocks 400 are levelled with and flush with the surface 200T′ of the semiconductor die(s) 200 and the top surface 230T of the molding compound 230. In some embodiments, as the interlink blocks 400 are planarized to become thinner, portions of the encapsulant 430 and portions of the TIVs 420 are removed (polished or grinded) but the ends of the TIVs 420 are still exposed from the encapsulant 430 for further electrical connection. Through the trimming process(es) and the planarization process, the semiconductor die(s) 200 and the interlink blocks 400 in the molded structure 17′ have substantially the same height (or thickness) in the thickness direction (Z-direction). As seen in FIG. 11, the molding compound 230 wraps around and covers entire sidewalls of the interlink blocks 400 and the semiconductor die(s) 200, and the TIVs 420 are laterally wrapped by the encapsulants 430 of the interlink blocks 400 but the TIVs 420 are separate from the molding compound 230 by the encapsulants 430.

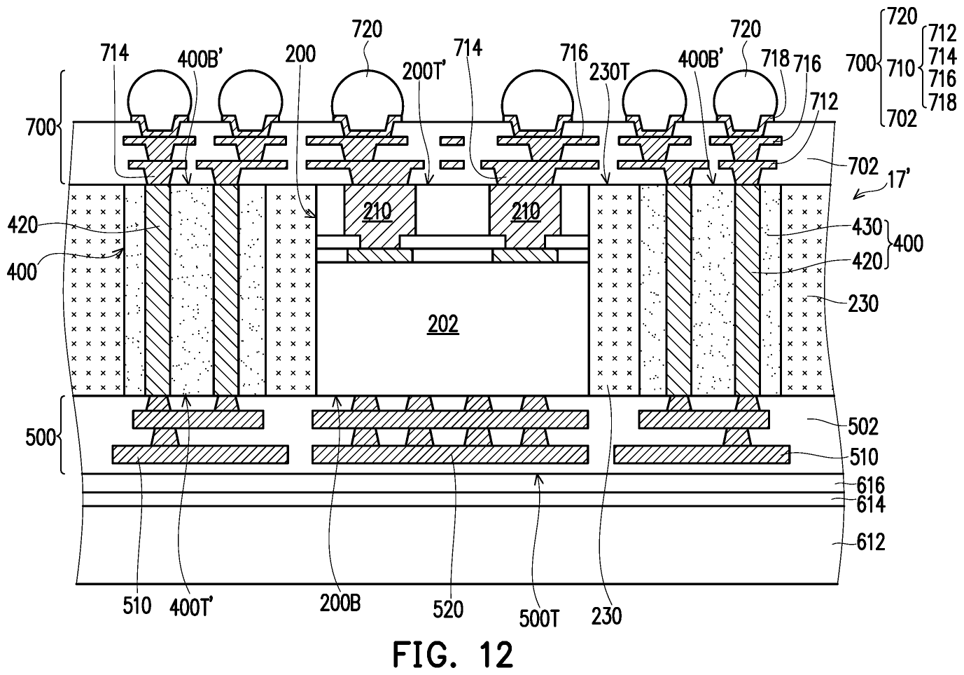

Referring back to FIG. 12, in some embodiments, a redistribution layer 700 is formed on the molding compound 230, on the semiconductor die(s) 200 and on the interlink blocks 400. In some embodiment, the redistribution layer 700 is formed on the surfaces 400B′ of the interlink blocks 400 and on the surface 200T′ of the semiconductor die(s) 200. Similarly, the formation of the redistribution layer 700 includes sequentially forming one or more layers of dielectric materials and one or more metallization layers in alternation. In certain embodiments, the redistribution layer 700 includes at least wiring layers 710 sandwiched between the dielectric material 702. In some embodiments, the bottommost wiring layer 712 of the wiring layers 710 include metallic vias 714 respectively connected to the conductive posts 210 of the semiconductor die(s) 200 and the TIVs 420 of the interlink blocks. In FIG. 12, the bottommost wiring layer 712 of the wiring layers 710 is physically and electrically connected to the TIVs 420 of the interlink blocks 400 and the conductive posts 210 of the semiconductor die 200.

In some embodiments, contact pads 718 are formed on a topmost wiring layer 716 of the wiring layers 710 and contact terminals 720 are formed on the contact pads 718. In some embodiments, the material of the wiring layers 710 includes copper, titanium, nickel, aluminum, tungsten, silver and/or alloys thereof. In some embodiments, the material of the dielectric material 702 includes polyimide, BCB, or PBO. In some embodiments, the contact terminals 720 include micro bumps, ball grid array (BGA) connectors, controlled collapse chip connection (C4) bumps, electroless nickel-electroless palladium-immersion gold technique (ENEPIG) formed bumps, or the like. For example, the contact terminals 720 may include a metallic material such as solder, copper, aluminum, gold, nickel, silver, palladium, tin, or combinations thereof. In some embodiments, the contact terminals 720 are formed through evaporation, electroplating, printing, solder transfer, ball placement, or the like. In an embodiment, material of the contact pads 718 may include titanium, copper, nickel, tungsten, gold or combinations thereof.

In some embodiments, as the redistribution layer 700 is formed on the active surface of the semiconductor die(s) 200, the redistribution layer 700 may be considered as a frontside redistribution layer electrically connected with the TIVs 420 of the interlink blocks 400 and electrically connected with the semiconductor die(s) 200. In some embodiments, the redistribution layers 500 and 700 are electrically connected via the through insulator vias (TIVs) 420 of the interlink blocks 400, and the semiconductor die(s) is electrically connected with the redistribution layers 500 and 700 and electrically connected with the TIVs 420.

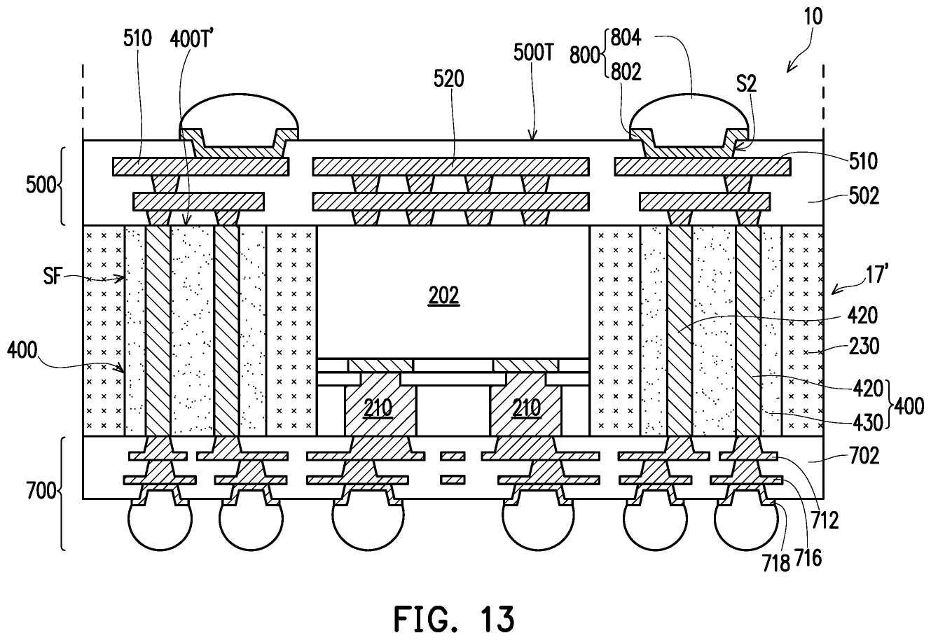

Referring to FIG. 12 and FIG. 13, after turning the whole structure upside down and detaching and removing the carrier 612 from the molded structure 17′, the surface 500T of the redistribution layer 500 is exposed. Later, in some embodiments, openings S2 are formed in the dielectric material 502 of the redistribution layer 500 to expose the topmost layer of the wiring patterns 510. Later, as seen in FIG. 13, connectors 800 are formed by forming under bump metallurgy (UBM) patterns 802 inside the openings S2 on the topmost layer of the wiring patterns 510, and forming bumps 804 respectively on the UBM patterns 802. In some embodiments, the connectors 800 include controlled collapse chip connection (C4) bumps, solder bumps, ball grid array (BGA) balls, or the like. In some embodiments, the arrangement and configurations of the connectors 800 may be determined based on circuit designs. In an embodiment, the UBM patterns 802 include three layers of metallic materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the UBM patterns 802.

In some embodiments, a singulation process is performed to cut through at least the redistribution layers 500, 700 and the molding compound 230 along the cutting lanes (represented by the dotted lines) to individualize the semiconductor packages 10. In one embodiment, the singulation process is a wafer dicing process including mechanical sawing or laser cutting. As seen in FIG. 13, in some embodiments, the performed dicing process cuts through the molding compound 230 of the molded structure 17′ but does not cut the interlink blocks 400 (i.e. without cutting through the encapsulants 430 of the interlink blocks 400).

In exemplary embodiments, the manufacturing method(s) described above is part of the packaging processes, and a plurality of semiconductor packages 10 is obtained after the wafer dicing process. During the packaging processes, the semiconductor package structure 10 may be further mounted with additional packages, chips/dies or other electronic devices.

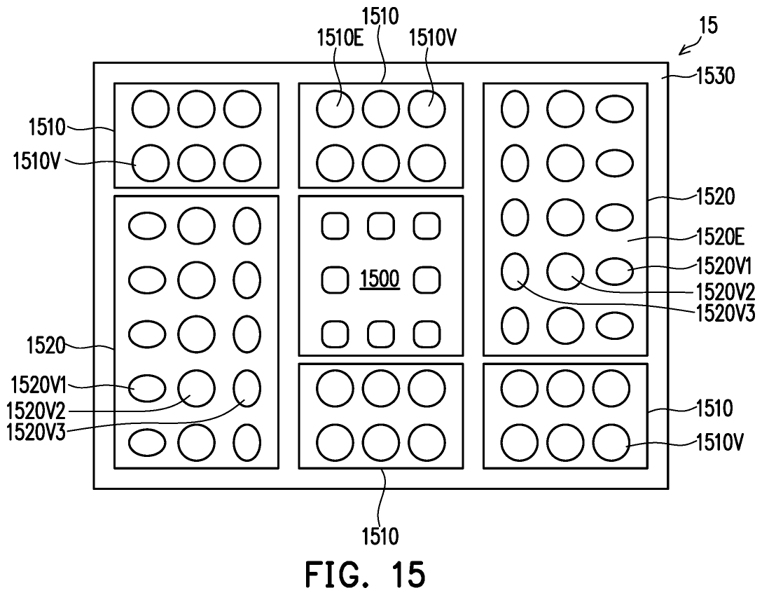

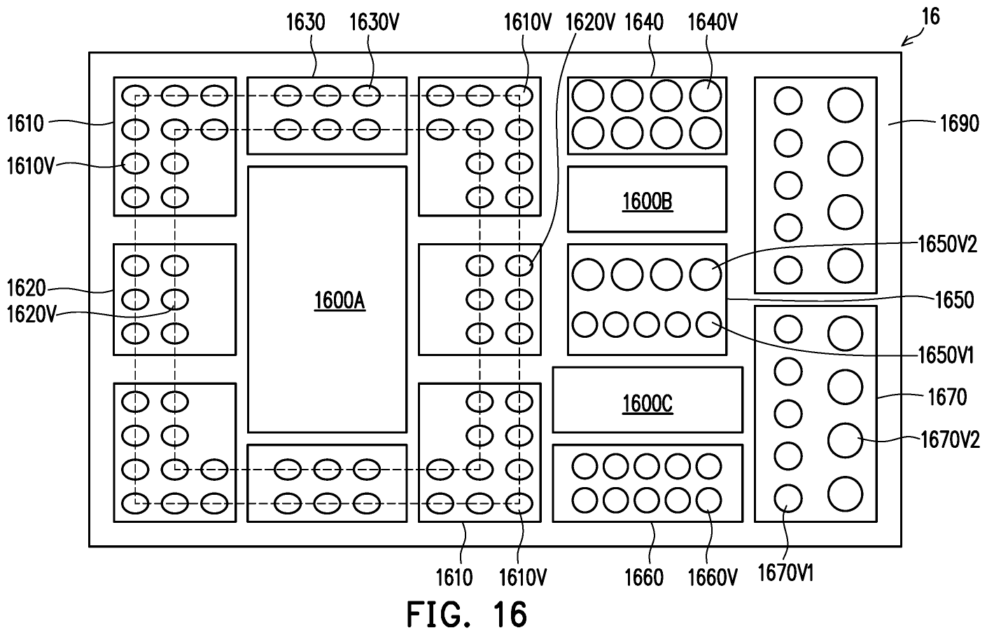

According to the present disclosure, different types of interlink blocks or interlink blocks having more than one types of TIVs may be applied or assembled into the package structures. FIG. 15 and FIG. 16 are schematic top views illustrating portions of semiconductor packages according to some exemplary embodiments of the present disclosure. In order to show the arrangement of the interlink blocks relative to the semiconductor die(s), other elements such as redistribution layers and connectors are omitted for illustration purposes.

From the top view of FIG. 15, in some embodiments, the molded structure of the package 15 includes a semiconductor die 1500 and interlink blocks 1510 and 1520 arranged around the semiconductor die 1500, and a molding compound 1530 laterally wrapping the semiconductor die 1500 and the interlink blocks 1510 and 1520. In some embodiments, the interlink blocks 1510 are similar to the interlink blocks 135A as described in previous paragraphs, and the interlink blocks 1520 are similar to the interlink block 135E as described in previous paragraphs. In FIG. 15, the interlink blocks 1510 that include TIVs 1510V arranged in an array and wrapped by encapsulants 1510E. The interlink blocks 1520 include TIVs 1520V1, 1520V2, 1520V3 respectively aligned in columns and wrapped by encapsulants 1520E. In FIG. 15, in some embodiments, the interlink blocks 1510 are disposed by two opposite sides of the semiconductor die 1500, and the interlink blocks 1520 are disposed by the other two opposite sides of the semiconductor die 1500. From the schematic top view, the TIVs 1510V, 1520V1, 1520V2 and 1520V3 are arranged as rings surrounding four sides of the semiconductor die 1500.

In some embodiments, as seen in the top view of FIG. 16, the package 16 includes at least three types of dies including a first semiconductor die 1600A, a second semiconductor die 1600B, a third semiconductor die 1600C, and interlink blocks 1610, 1620, 1630, 1640, 1650, 1660, 1670 arranged around the semiconductor dies 1600A, 1600B, 1600C, and a molding compound 1690 laterally wrapping the semiconductor dies 1600A, 1600B, 1600C and the interlink blocks 1610, 1620, 1630, 1640, 1650, 1660, 1670. The interlink blocks may be similar to the interlink blocks as described in FIG. 14A-FIG. 14F and in the previous paragraphs In some embodiments, the interlink blocks 1610 that include TIVs 1610V arranged in L shapes are disposed near the corners of the semiconductor die 1600A, while the interlink blocks 1620 and 1630 that include TIVs 1620V and 1630V are disposed at four sides of the semiconductor die 1600A. From the schematic top view, the TIVs 1610V, 1620V, 1630V are arranged as rings surrounding four sides of the semiconductor die 1600A. In FIG. 16, the semiconductor die 1600B is disposed between the interlink blocks 1640 and 1650, and between the interlink blocks 1610, 1620 and 1670. In FIG. 16, the semiconductor die 1600C is disposed between the interlink blocks 1650 and 1660, and between the interlink block 1670, 1620, 1610. In some embodiments, the interlink block 1650 includes TIVs 1650V1 and larger TIVs 1650V2 (with a larger diameter), and the interlink blocks 1670 include TIVs 1670V1 and larger TIVs 1670V2 (with a larger diameter). From the schematic top view, the semiconductor dies 1600B and 1600C are surrounded by the TIVs 1610V. 1620V, 1640V. 1650V1, 1650V2, 1660V. 1670V1 and 1670V2.

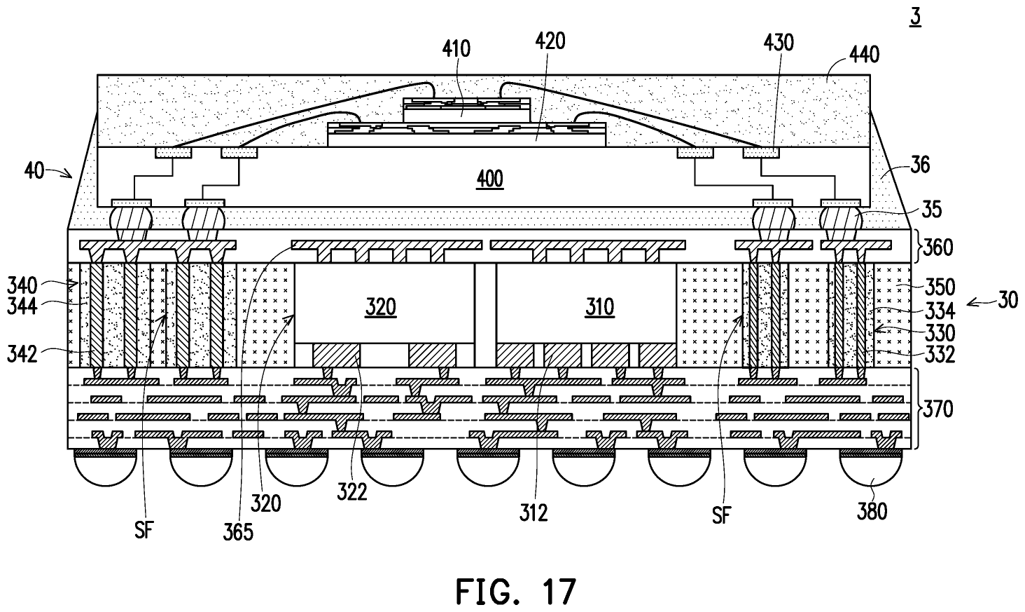

FIG. 17 is a schematic cross-sectional view illustrating a semiconductor package according to some exemplary embodiments. In FIG. 17, a semiconductor package structure 3 including a top package 40 mounted on and electrically connected with a bottom package 30 through the conductive connectors 35 is described. In some embodiments, the bottom package 30 is an integrated fan-out (InFO) package, and the semiconductor package structure 3 is an InFO package-on-package (InFO POP) structure. As shown in FIG. 13, the InFO POP structure 3 includes an underfill material 36 filled between the top package 40 and the bottom package 30. In some embodiments, the top package 40 includes stacked dies 410 and 420 wire-bonded to contacts 430 of a substrate 400, and a molding layer 440 is formed over the substrate 400 to encapsulate semiconductor dies 410 and 420. In some embodiments, the dies 410 and 420 include different types of chips including memory chips and logic chips. It is understood that the dies 410 and 420 may be bonded using suitable methods such as bonding wires, bumps, or ball grid array (BGA) balls, to the substrate 400. In some embodiments, the dies 410, 420 are electrically coupled to the below bottom package 30 through the substrate 400 and the conductive connectors 35.

In some embodiments, the bottom package 30 may be fabricated following the manufacturing processes as described in the previous paragraphs and similar to the package structure as shown in FIG. 13. Referring to FIG. 17, in exemplary embodiments, the semiconductor package 30 comprises a first semiconductor die 310, a second semiconductor die 320, first interlink blocks 330, and second interlink blocks 340 laterally wrapped by a molding compound 350. In some embodiments, the package 30 includes an upper redistribution layer 360 and a lower redistribution layer 370 located on two opposite sides of the molding compound 350, and connectors 380 located on the lower redistribution layer 370. In some embodiments, the first semiconductor die 310 and the second semiconductor die 320 perform different functions or includes different types of chips. In some embodiments, the conductive posts (contacts) 312 of the first semiconductor die 310 have a critical dimension smaller than that of the conductive posts (contacts) 322 of the second semiconductor die 320. In some embodiments, the sizes (e.g., diameters) of the TIVs 332 in the first interlink blocks 330 are smaller than the sizes (e.g., diameters) of the TIVs 342 in the second interlink blocks 340. In some embodiments, for matching the contact layout or contact sizes of the nearby die(s), different types of TIVs (different cross-section area sizes, shapes or pitches) or different types of interlink blocks are arranged. In some embodiments, the TIVs 332 and 342 penetrating through the interlink blocks 330 and 340 are in physical contact with the metallization layers of the upper and lower redistribution layers 360 and 370. In some embodiments, the upper redistribution layer 360 includes metallic thermal dissipating grid pattern 365 above the first semiconductor die 310 and the second semiconductor die 320, and the thermal dissipating pattern 365 is electrically floating and functions for assisting the heat dissipation of the first semiconductor die 310 and the second semiconductor die 320.

In some embodiments, a material of the molding compound 350 is different from a material of the insulating encapsulant 334 of the first interlink block(s) 330 and different from a material of the insulating encapsulant 344 of the second interlink block(s) 340. In some embodiments, the material of the molding compound 350 includes fillers, and the material of the insulating encapsulant 334 and/or the material of the insulating encapsulant 344 contains no fillers or fillers of smaller particle sizes. In some embodiments, there are interfaces SF existing between the interlink blocks 330, 340 and the molding compound 350.

By forming the interlink blocks and molding compound individually, larger process windows for the trimming process(es) and the planarization process(es) and flexibility in material choices are offered, and the reliability for the package(s) is improved. Corresponding to particle sizes of the fillers contained in the material of the molding compound and the materials of the encapsulants of the interlink blocks, the insulating molding material without containing filler offers better filling capability and provides a better planarized surface after the planarization process, which further improves the warpage of the structure.

According to some embodiments, a semiconductor package including a first redistribution layer, a semiconductor die, an interlink block, and a molding compound is disclosed. The semiconductor die is disposed on the first redistribution layer, with an active surface of the semiconductor die facing the first redistribution layer. The interlink block is disposed on the first redistribution layer and beside the semiconductor die. The interlink block includes an insulating encapsulant and first through insulator vias (TIVs) penetrating through the insulating encapsulant. The molding compound is disposed on the first redistribution layer and laterally wraps around the semiconductor die and the interlink block. The interlink block is spaced apart from the semiconductor die with the molding compound there-between. The first TIVs are isolated from the molding compound by the insulating encapsulant. The first TIVs are electrically connected with the first redistribution layer.

According to some embodiments, a semiconductor package including first and second redistribution layers, a semiconductor die, an interlink block, and a molding compound is disclosed. The first redistribution layer includes a plurality of wiring layers. The semiconductor die overlies the first distribution layer. The interlink block is disposed beside the semiconductor die and overlies the first redistribution layer. The interlink block includes an encapsulant and a through insulation via extending through the encapsulant. The through insulation via directly contacts at least one of the plurality of wiring layers of the first redistribution layer. The molding compound is disposed between the semiconductor die and the interlink block.

According to some embodiments, a manufacturing method for semiconductor packages is disclosed. Interlink blocks are formed, and each interlink block includes through insulator vias laterally wrapped by an encapsulant. Semiconductor dies are provided over a first carrier with active surfaces of the semiconductor dies facing the first carrier. The interlink blocks are provided on the first carrier and beside the semiconductor dies. A molding compound is formed over the first carrier, encapsulating the semiconductor dies and the interlink blocks to form a molded structure. A first trimming process is performed to the molded structure to expose the through insulator vias. A first redistribution layer is formed over the semiconductor dies and the interlink blocks. The first redistribution layer is electrically connected with the through insulator vias. A second carrier is attached to the first redistribution layer, and the first carrier is detached from the molded structure. A second trimming process is performed to the molded structure to expose the through insulator vias. A second redistribution layer is formed over the semiconductor dies and the interlink blocks. The second redistribution layer is electrically connected with the through insulator vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first redistribution layer;
a semiconductor die disposed on the first redistribution layer, wherein an active surface of the semiconductor die faces the first redistribution layer;
an interlink block, disposed on the first redistribution layer and beside the semiconductor die, wherein the interlink block includes an insulating encapsulant and first through insulator vias (TIVs) penetrating through the insulating encapsulant; and
a molding compound, disposed on the first redistribution layer and laterally wrapping around the semiconductor die and the interlink block,
wherein the interlink block is spaced apart from the semiconductor die with the molding compound there-between, and the first TIVs are isolated from the molding compound by the insulating encapsulant, and
wherein the first TIVs are electrically connected with the first redistribution layer.

2. The semiconductor package as claimed in claim 1, wherein a material of the insulating encapsulant is different from a material of the molding compound.

3. The semiconductor package as claimed in claim 1, wherein the molding compound fully covers sidewalls of the interlink block, and there are interfaces between the insulating encapsulant of the interlink block and the molding compound surrounding the insulating encapsulant.

4. The semiconductor package as claimed in claim 1, further comprising a second redistribution layer disposed on a backside surface of the semiconductor die opposite to the active surface, over the interlink block and over the molding compound, and the semiconductor die and the first and second redistribution layers are electrically connected through the first TIVs of the interlink block located there-between.

5. The semiconductor package as claimed in claim 4, wherein the second redistribution layer includes a thermal dissipating pattern disposed over the semiconductor die and in contact with a semiconductor substrate of the semiconductor die.

6. The semiconductor package as claimed in claim 1, wherein a material of the molding compound includes first fillers, a material of the insulating encapsulant includes second fillers, and the first fillers have particle sizes larger than those of the second fillers.

7. The semiconductor package as claimed in claim 1, wherein at least one of the first TIVs in the interlink block is in direct contact to a wiring layer of the first redistribution layer.

8. The semiconductor package as claimed in claim 1, wherein at least one of the first TIVs in the interlink block is in direct contact to a topmost via of the first redistribution layer.

9. The semiconductor package as claimed in claim 1, further comprising another interlink block including second TIVs, wherein the first and second TIVs have substantially a same height, and each first TIV has a cross-section area size different from that of each second TIV.

10. A semiconductor package, comprising:
a first redistribution layer including a plurality of wiring layers;
a semiconductor die overlying the first distribution layer;
an interlink block, disposed beside the semiconductor die and overlying the first redistribution layer, wherein the interlink block includes an encapsulant and a through insulation via extending through the encapsulant, and the through insulation via directly contacts at least one of the plurality of wiring layers of the first redistribution layer; and
a molding compound disposed between the semiconductor die and the interlink block.

11. The semiconductor package as claimed in claim 10, wherein the semiconductor die includes a first semiconductor die and a second semiconductor die perform different functions from the first semiconductor die.

12. The semiconductor package as claimed in claim 10, wherein the interlink block include a first interlink block including a first through insulation via, and a second interlink block including a second through insulation via, the first interlink block and the second interlink block are arranged beside and around the semiconductor die, and the first through insulation via has a cross-section area size different from that of the second through insulation via.

13. The semiconductor package as claimed in claim 10, wherein the through insulation vias include a first through insulation via and a second through insulation via inside the interlink block, and the first through insulation via has a cross-section area size different from that of the second through insulation via.

14. The semiconductor package as claimed in claim 10, further comprising a second redistribution layer having a thermal dissipating pattern, wherein the thermal dissipating pattern is disposed over the semiconductor die and in contact with a semiconductor substrate of the semiconductor die.

15. The semiconductor package as claimed in claim 10, wherein the molding compound laterally wraps the semiconductor die and the interlink block with interfaces between the interlink block and the molding compound.

16. A manufacturing method for semiconductor packages, comprising:
forming interlink blocks, wherein the interlink block includes through insulator vias laterally wrapped by an encapsulant;
providing semiconductor dies over a first carrier with active surfaces of the semiconductor dies facing the first carrier;
providing the interlink blocks on the first carrier and beside the semiconductor dies;
forming a molding compound over the first carrier, encapsulating the semiconductor dies and the interlink blocks to form a molded structure;
performing a first trimming process to the molded structure to expose the through insulator vias;
forming a first redistribution layer over the semiconductor dies and the interlink blocks, wherein the first redistribution layer is electrically connected with the through insulator vias;
attaching a second carrier to the first redistribution layer;
detaching the first carrier from the molded structure;
performing a second trimming process to the molded structure to expose the through insulator vias; and
forming a second redistribution layer over the semiconductor dies and the interlink blocks, wherein the second redistribution layer is electrically connected with the through insulator vias.

17. The method as claimed in claim 16, further comprising performing a dicing process cutting through the molding compound of the molded structure and the first and second redistribution layers to form individual semiconductor packages.

18. The method as claimed in claim 16, wherein the first redistribution layer is formed directly on and in contact with semiconductor substrates of the semiconductor dies.

19. The method as claimed in claim 18, wherein the first redistribution layer is formed with a thermal dissipation pattern above the semiconductor dies and in contact with the semiconductor substrates.

20. The method as claimed in claim 16, wherein the molding compound is formed with a first material with fillers, and the interlink blocks are formed with a second material without fillers for encapsulating the through insulator vias, and the first material with fillers is different from the second material without fillers.
